(19) United States
(12) Patent Application Publication
(10) Pub. No.: US 2010/0090284 A1
(43) Pub. Date: Apr. 15, 2010

(54) METAL-OXIDE-SEMICONDUCTOR DEVICE

(76) Inventors: Yen-Wei Liao, Miaoli County (TW); Sheng-Yuan Yang, Taipei County (TW); Cheng-Yu Fang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/323,475

(22) Filed: Nov. 26, 2008

(30) Foreign Application Priority Data
Oct. 13, 2008 (TW) 097139168

(51) Int. Cl. H01L 29/78

(52) U.S. Cl. 257/355; 257/E29.255

(57) ABSTRACT

A metal-oxide-semiconductor device includes a substrate, a gate on the substrate, a source in the substrate and adjacent to one side of the gate, a drain in the substrate and adjacent to another side of the gate, a gate channel in the substrate and under the gate, and a gate insulator between the source and the drain and the gate and the gate channel, wherein the gate insulator has a substantially uneven thickness for use in electrostatic discharge (ESD) protection.

### BACKGROUND OF THE INVENTION

1. Field of the Invention

The present invention relates to a metal-oxide-semiconductor. In particular, the present invention relates to a metal-oxide-semiconductor for use in electrostatic discharge protection.

2. Description of the Prior Art

Electrostatic discharge (ESD) is a major factor responsible for the damage of electrical overstress (EOS) of most electronic elements or electronic systems. The damaged electronic elements or electronic systems may be either temporarily disabled or permanently destroyed. This kind of unexpected electrical overstress destruction results in the damage of the electronic elements, adversely influencing the integrated circuits (IC) and making the electronic products fail to function.

The causes of the electrostatic discharge may come from various reasons and are usually inevitable. Static charges may accumulate in human bodies, devices, storages equipments during the manufacture, assembly, testing, storage of the electronic elements or electronic systems, even the electronic elements themselves may accumulate static charges. Static charges discharge when objects contact one another and damage takes its toll.

The object to equip the integrated circuits with the electrostatic discharge protection circuit is to protect the integrated circuits from the damage of the electrostatic discharge. The CMOS technique dominates the current semiconductor circuits. The electrostatic discharge may harm the delicate semiconductor chips in many ways. For example, the discharged charges punch through the thin gate insulator inside the elements or harm MOSFET and CMOS. Accordingly, if the integrated circuits are equipped with the electrostatic discharge protection circuit, they may function normally in the presence of the electrostatic discharge. On the contrary, the integrated circuits without the electrostatic discharge protection circuit may not function well in the presence of the electrostatic discharge. Even further, the chip may be partially disabled or potentially destroyed without obvious signs.

There are some known electrostatic discharge protection circuits. The first one is called a thin oxide device. FIG. 1 illustrates the conventional thin oxide device. The thin oxide device employs the parasitic NPN bipolar junction transistor (BJT) to protect the core circuit. Although the thin oxide device is more sensitive due to lower triggering voltage, the thin oxide device has lower tolerance to the high voltage discharge because the triggered electrostatic discharge current path is close to the surface of the Si substrate and thermal breakdown happens easily.

The second one is called a field oxide device. FIG. 2 illustrates the conventional field oxide device. The field oxide device also employs the parasitic NPN bipolar junction transistor (BJT) to protect the core circuit. The field oxide device keeps the triggered electrostatic discharge current path away from the surface of the Si substrate because field oxide is much thicker. However, the field oxide device is much less sensitive than the thin oxide device and cannot protect the interior circuit well.

The third one is called a modified electrostatic discharge protection device. FIG. 3 illustrates the equivalent circuit diagram of the modified electrostatic discharge protection device. The modified electrostatic discharge protection device employs an independent thin oxide device plus an extra resistance R to drive another independent field oxide device to be electrostatic discharge protective. When the electrostatic discharge happens, the thin oxide device of lower triggering voltage is first activated. The parasitic NPN bipolar junction transistor (BJT) is activated to let the electrostatic discharge current pass the thin oxide device. The resistance R then raises the voltage of the coupled field oxide device to drive the parasitic NPN bipolar junction transistor in the field oxide device to be on to protect the core circuit. However, if the resistance R is incorrectly designed, the field oxide device cannot be driven on. Besides, additional resistance R of a particular value is needed to be added in the circuits to match the thin oxide device and the field oxide device, which causes the design of the circuit more difficult and complicated.

Therefore, a novel discharge protection device is needed not only to be compatible with the current metal-oxide-semiconductor process, but also cope with wide range of discharge voltage to cover both high and low voltage discharge to achieve a complete electrostatic discharge protection.

### SUMMARY OF THE INVENTION

Accordingly, the present invention proposes a novel electrostatic discharge protection device for use in electrostatic discharge protection. Because the fundamental structure of the novel electrostatic discharge protection device of the present invention is based on the metal-oxide-semiconductor, the process to manufacture the novel electrostatic discharge protection device is of course compatible with the current metal-oxide-semiconductor process, so the design of the novel electrostatic discharge protection device is much less difficult and complicated. In addition, because of the novel core structure, the novel electrostatic discharge protection device for use in electrostatic discharge protection is responsible to cope with wide range of discharge voltage and to cover both high and low voltage discharge to achieve a complete electrostatic discharge protection.

The metal-oxide-semiconductor device of the present invention includes a substrate, a gate disposed on the substrate, a source disposed in the substrate and adjacent to one side of the gate, a drain disposed in the substrate and adjacent to another side of the gate, a gate channel disposed in the substrate and under the gate, and a gate insulator disposed between the source and the drain as well as between the gate channel and the gate, wherein the gate insulator has a substantially uneven thickness for use in the electrostatic discharge protection.

In the novel electrostatic discharge protection device of the present invention for use in electrostatic discharge protection, because the field oxide device replaces part of the gate insulator under the gate, the process to manufacture the electrostatic discharge protection device is of course compatible with the current metal-oxide-semiconductor process, and the design of the novel electrostatic discharge protection device is much less difficult and complicated. Still, the electrostatic discharge protection device of the present invention is responsible for a wide range of discharge voltage to cover all high, medium and low voltage discharge to achieve a complete electrostatic discharge protection.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates the conventional thin oxide device.

FIG. 2 illustrates the conventional field oxide device.

FIG. 3 illustrates the equivalent circuit diagram of the modified electrostatic discharge protection device.

FIGS. 4-6 illustrate various possible embodiments of the gate insulator with a substantially uneven thickness of the present invention.

FIG. 7-8 illustrates a distribution of the thickness of the gate insulator of the present invention between the source and the drain.

FIG. 9 illustrates the equivalent circuit diagram of the novel metal-oxide-semiconductor device of the present invention.

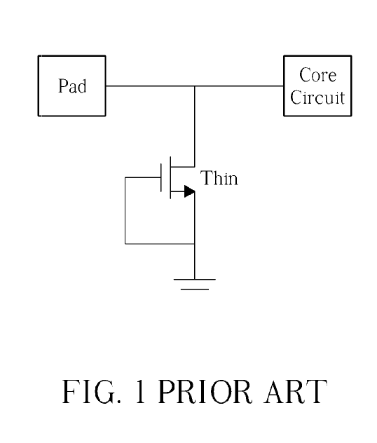

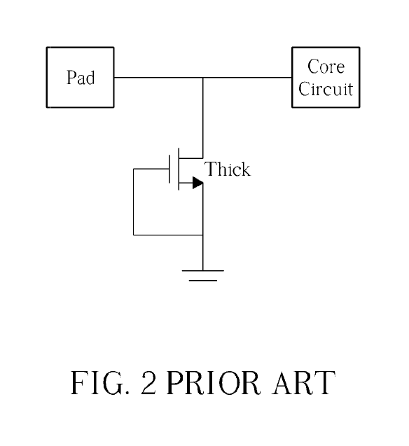

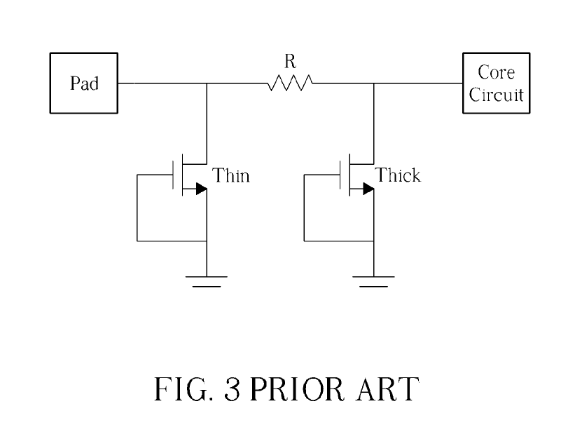

### DETAILED DESCRIPTION

The present invention provides a metal-oxide-semiconductor device for use in electrostatic discharge protection. First, the electrostatic discharge protection device of the present invention is based on the structure of the metal-oxide-semiconductor device, so the process to manufacture the electrostatic discharge protection device is surely compatible with the current metal-oxide-semiconductor process, and the design of the novel electrostatic discharge protection device is much less difficult and complicated. Second, the metal-oxide-semiconductor device of the present invention for use in electrostatic discharge protection has a substantially changeable thickness, so the metal-oxide-semiconductor device of the present invention for use in electrostatic discharge protection is responsible for a wide range of discharge voltage to cover all high, medium and low voltage discharge to achieve a complete electrostatic discharge protection.

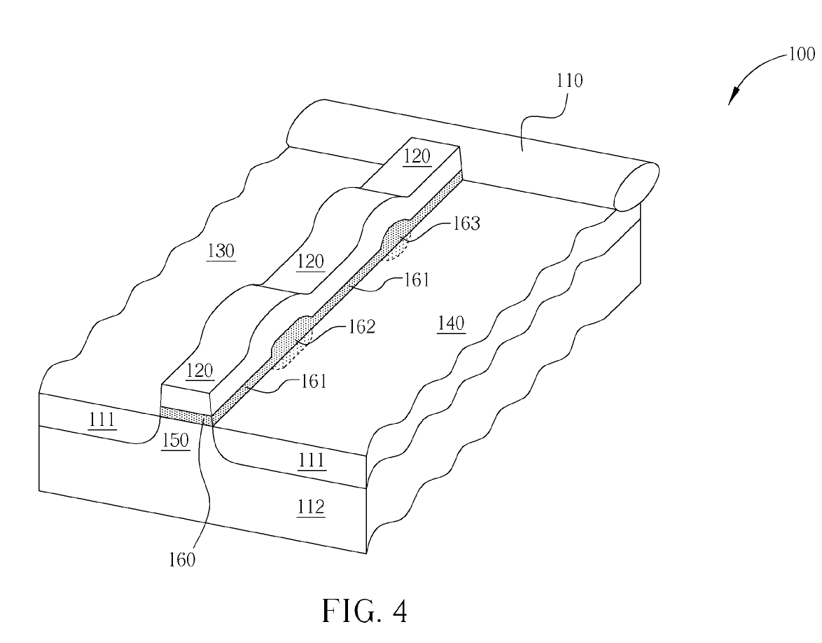

The present invention provides a metal-oxide-semiconductor device for use in electrostatic discharge protection. FIG. 4 illustrates a preferred embodiment of the metal-oxide-semiconductor device of the present invention. The metal-oxide-semiconductor device 100 of the present invention includes a substrate 110, a gate 120, a source 130, a drain 140, a gate channel 150 and a gate isolation layer 160. The substrate may be a semiconductor material, such as Si or SOI. Optionally, the substrate 100 may have additional various doped regions. FIG. 4 illustrates a P-well 112 in the substrate 110 and an N+doping region 111 serving as the source 130 and the drain 140.

The gate 120 is disposed on the substrate 110 and the source 130 and the drain 140 are respectively disposed on both sides of the gate 120 to form a standard metal-oxide-semiconductor structure. There are two sets of gate 120, source 130 and drain 140 illustrated in FIG. 4. Still, the gate channel 150 is located in the substrate 110, under the gate 120, and between the source 130 and the drain 140, for the charged carriers to move.

The gate insulator 160 is disposed under the gate 120 to serve as electrical isolation. In addition, the gate insulator 160 may also be deemed as disposed between the source 130 and the drain 140, or between the gate channel 150 and the gate 120. The gate insulator 160 in the metal-oxide-semiconductor device 100 of the present invention may include oxide or nitride and is useful for electrostatic discharge (ESD) protection.

Part of the gate insulator 160 in the metal-oxide-semiconductor device 100 of the present invention is replaced with field oxide layer, so the gate insulator 160 has a substantially uneven thickness for use in the electrostatic discharge protection. Such substantially uneven thickness may be continuous change of thickness or non-continuous change of thickness. In one preferred embodiment of the present invention, the non-continuous change of thickness may be stepwise. The continuous change of thickness may be alternate along the extension direction of width of the gate channel.

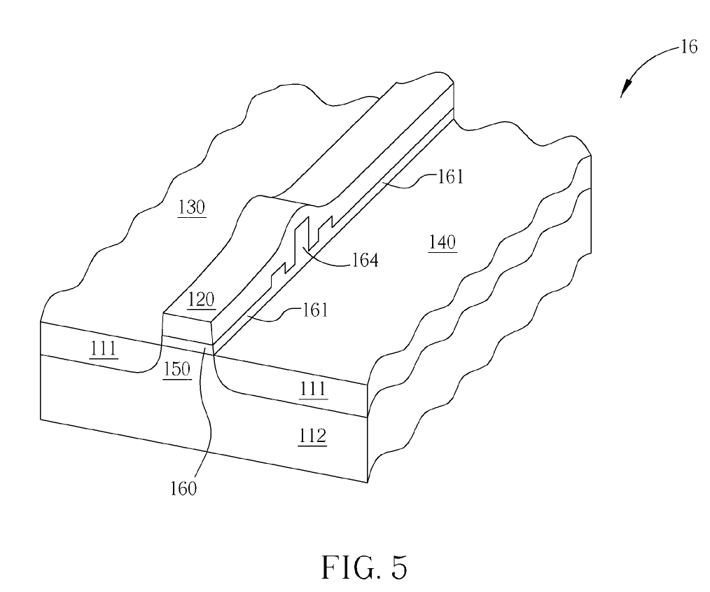

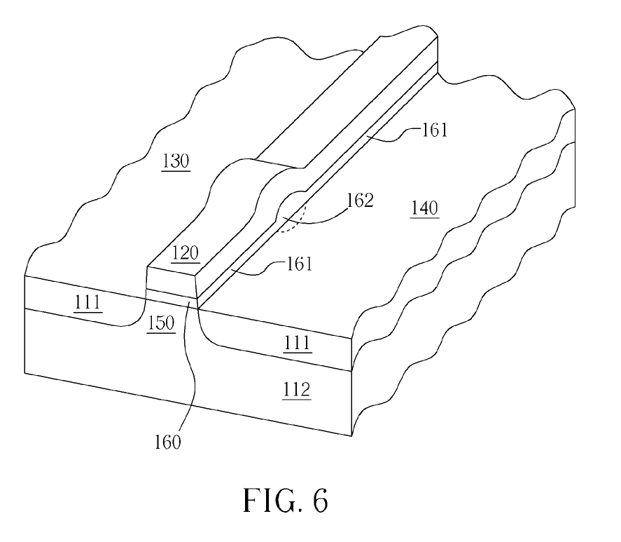

FIGS. 4-6 illustrate various possible embodiments of the gate insulator with a substantially uneven thickness of the present invention. For example, as shown in FIG. 4, the gate insulator 160 includes at least an insulator layer 161 and at least a field oxide (FOX) layer 162. The insulator layer 161 has roughly the same thickness. Relatively, the thickness of the field oxide (FOX) layer 162 is about the same near the center and in the shape of bird's beak at both ends. Or, the field oxide (FOX) layer 162 is in a shape of olive. Besides, the gate insulators in other embodiments may be insulator layers connected by different thickness, as shown in FIG. 5, the insulator layer 164 is illustrated in a stepwise shape. In a more preferred embodiment of the present invention, the thickness of the gate insulator 164 in the metal-oxide-semiconductor for use in electrostatic discharge protection is higher near the center and lower at the ends. Still, in an even more preferred embodiment of the present invention, the thickness of the gate insulator is at its highest near the center between the source and the drain, as shown in FIG. 6.

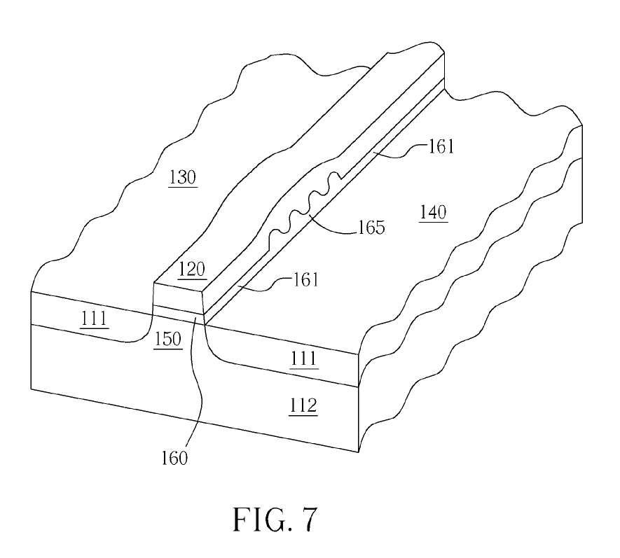

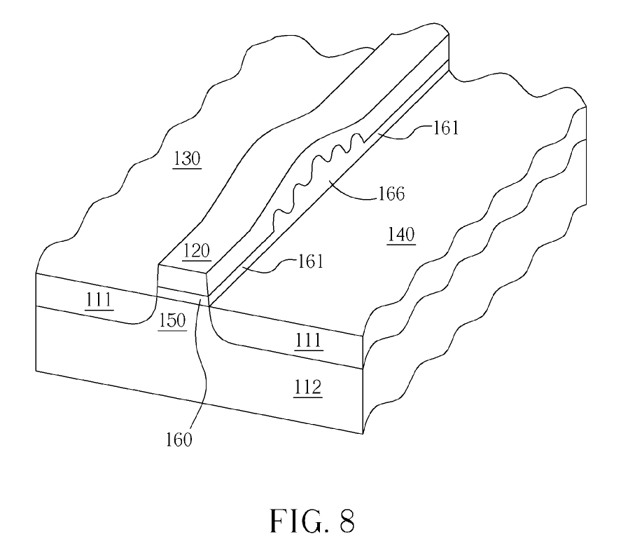

FIG. 7-8 illustrates a distribution of the thickness of the gate insulator of the present invention between the source and the drain. The distribution of the thickness of the gate insulator of the present invention between the source and the drain may be presented in a pre-determined pattern. For example, the gate insulator 165 illustrates an alternate distribution and the gate insulator 165 illustrates a wave-like distribution. The gate insulator 165 illustrates an equidistant distribution (a same space distribution). The gate insulator 166 illustrates a non-equidistant distribution (a different space distribution).

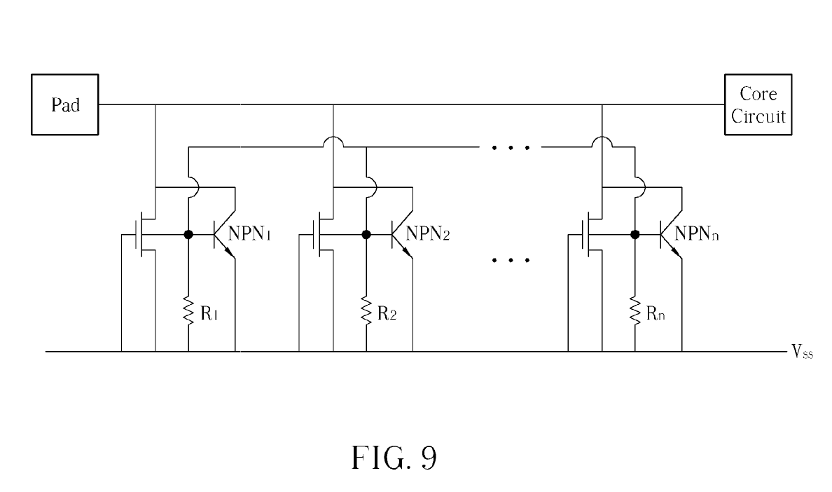

The metal-oxide-semiconductor device of the present invention is equivalent to a thin oxide device parallel with several field oxide devices. FIG. 9 illustrates the equivalent circuit diagram of the novel metal-oxide-semiconductor device of the present invention. Each field oxide device has a unique and different parasitic resistance R, depending on the gate insulator 160 which the field oxide device is attached to. The more distant the semiconductor device is from the p-well 112 contact window (not shown), the higher the parasitic resistance R is. Because the thickness of the gate insulator 160 changes in accordance with its location, the parasitic resistance R also changes in accordance with its distance to the p-well 112 contact window, it is equivalent to several semiconductor devices of different gate insulator thickness parallel with each other.

When electrostatic discharge happens, as mentioned before, the protective circuit of greater parasitic resistance R is first activated. The metal-oxide-semiconductor device used as the electrostatic discharge protection device (ESD) works In accordance with the phenomenon that the parasitic NPNs in the metal-oxide-semiconductor devices of gate insulator at different locations have different triggering potentials. With the electrostatic discharge continuing, the parasitic transistor NPN₁ in the field oxide device of the greatest parasitic resistance R₁ is then activated, so the electrostatic discharge current pass through NPN₁. When part of the electrostatic discharge current pass through the parasitic resistance R₂, the parasitic transistor NPN₂ in the field oxide device of the second greatest parasitic resistance R₂ is then activated to dissipate part of the electrostatic discharge current. In other words, by means such chain reaction, the parasitic transistors NPNₙ in the field oxide devices of the parasitic resistance R₃ . . . Rₙ which is slightly smaller than the parasitic resistance R₂ are activated one by one to keep on dissipating some of the electrostatic discharge current, till all the electrostatic discharge current is exhausted. The metal-oxide-semiconductor device of the present invention has enormous electrostatic discharge voltage load due to the regions of gate insulators of different thickness disposed in the metal-oxide-semiconductor device of the present invention at the same time. Thick gate insulators are disposed in the metal-oxide-semiconductor device without jeopardizing the triggering potential of the parasitic transistors NPN in the entire metal-oxide-semiconductor device. The thick gate insulators are used to enhance the capability of electrostatic discharge protection of the metal-oxide-semiconductor device.

Given the above, no matter what kind of electrostatic discharge happens, the metal-oxide-semiconductor device of the present invention is activated in accordance with the cascade effect to correspondingly dissipate the electrostatic discharge current, till all the electrostatic discharge current is exhausted. For example, if the gate insulator 160 has continuous change of thickness, the electrostatic discharge activates the cascade effect to dissipate the electrostatic discharge current, till all the electrostatic discharge current is exhausted. This effectively protects the electronic elements from the damages of the electrostatic discharge.

Those skilled in the art will readily observe that numerous modifications and alterations of the device and method may be made while retaining the teachings of the invention.

What is claimed is:

1. A metal-oxide-semiconductor (MOS) device, comprising:
a substrate;
a gate disposed on said substrate;
a source disposed in said substrate and adjacent to one side of said gate;
a drain disposed in said substrate and adjacent to another side of said gate;
a gate channel disposed in said substrate, under said gate and between said source and said drain; and
a gate insulator disposed between said gate channel and said gate, wherein said gate insulator has a substantially uneven thickness for use in electrostatic discharge (ESD) protection.

2. The metal-oxide-semiconductor device of claim 1, wherein said substrate is a semiconductor substrate.

3. The metal-oxide-semiconductor device of claim 1, wherein said gate insulator has a discontinuous change of thickness.

4. The metal-oxide-semiconductor device of claim 3, wherein said gate insulator has a stepwise change of thickness.

5. The metal-oxide-semiconductor device of claim 1, wherein said gate insulator has a continuous change of thickness.

6. The metal-oxide-semiconductor device of claim 5, wherein said gate insulator comprises a field oxide (fox) and an insulator layer of the same thickness.

7. The metal-oxide-semiconductor device of claim 1, wherein said gate insulator has a maximum thickness located at the center region between said source and said drain.

8. The metal-oxide-semiconductor device of claim 1, wherein said gate insulator has an alternative change of thickness along the width of said gate channel.

9. The metal-oxide-semiconductor device of claim 1, wherein said gate insulator has a predetermined distribution between said source and said drain.

10. The metal-oxide-semiconductor device of claim 9, wherein said predetermined distribution comprises an alternative distribution, a wave pattern distribution, an equidistant distribution and a non-equidistant distribution.

11. The metal-oxide-semiconductor device of claim 1, wherein said gate insulator comprises an oxide.
